(19) United States
(12) Patent Application Publication
(10) Pub. No.: US 2017/0125269 A1
(43) Pub. Date: May 4, 2017

(54) TRANSFER MODULE FOR A MULTI-MODULE APPARATUS

(71) Applicant: AIXTRON SE, Herzogenrath (DE)

(72) Inventors: Scott Dunham, Fremont, CA (US); Timothy O'Brien, Sunnyvale, CA (US); Tahir Zuberi, Milpitas, CA (US)

(73) Assignee: AIXTRON SE, Herzogenrath (DE)

(21) Appl. No.: 14/926,612

(22) Filed: Oct. 29, 2015

(51) Int. Cl. H01L 21/67; H01L 21/677; H01L 21/687

(52) U.S. Cl. CPC H01L 21/67196; H01L 21/68707; H01L 21/67748

(57) ABSTRACT

A transfer module for a multi-module apparatus may include a) a plurality of facets, wherein a facet of said plurality comprises a port configured to hold a module; and b) at least one robot arm configured to move an object to and from the module through said port via a combination of extension and rotational movements.

### FIELD

The present disclosure relates to a transfer module for a multi-module apparatus and more specifically, to a transfer module for a multi-module semiconductor processing apparatus.

### SUMMARY

One embodiment is a transfer module for a multi-module apparatus, comprising: a) a plurality of facets, wherein a facet of said plurality comprises a port configured to hold a module; and b) one or more robot arms each configured to move an object a) to and from the module through said port and b) between facets of said plurality via compound extension and rotational movements.

### FIGURES

FIG. 1 shows a top view of a transfer module having an irregular heptagonal shape.

FIG. 2A-C illustrate movements of robot arms in a transfer module. In particular, FIGS. 2A, 2B and 2C illustrate an extension of a first robot arm by showing the first arm in a contracted state, such as the first arm is entirely in an inner volume of the transfer module, in a semi-extended state and in a fully extended state, respectively. FIGS. 2A-C also illustrate a rotational movement for a second robot arm. Each of the robot arms may perform compound extension and rotation movements.

### DETAILED DESCRIPTION

Unless otherwise specified “a” or “an” means one or more.

Many of existing transfer modules of multi-module apparatus, i.e. apparatuses with multiple processing modules, in the semiconductor industry form in a horizontal cross-section an equal sided polygon with angles derived by the formula 360/(number of facets). An access to edges of an individual process module for such multi-module apparatuses may become extremely tight as an adjacent process module(s)' sides may approach an angle of the transfer module. An access under the transport module may be further restricted by these same angles. One solution to allow for access in a regular polygon module may be increasing a length of a facet of an equal sided polygon multi-module apparatus, whereby greatly increasing an area footprint of the apparatus. Attaching one or more external buffer stations, i.e. stations for storing wafers not being used by a processing module of the apparatus, to the transfer module may also increase the footprint of the apparatus and/or reduce the quantity of facets available for process modules.

The present inventors designed an irregular Heptagon transfer module for a multi-module apparatus. Such transfer module allows utilizing densely packed process modules while incorporating a greater amount of a process room in a defined limited space. The designed transfer module may provide an internal space for storing wafers within the vacuum environment of the transfer module. The stored wafers may be, for example, i) cover (dummy) wafers, which may be used, for example, for testing one or more individual processing modules of the multi-module apparatus and/or making a first run of an processing module; ii) cleaned, but not processed wafers. Storing of cleaned, but not processed wafers in the vacuum environment of the transfer module may allow eliminating native growth oxides on a clean wafer, while waiting for a particular processing module to become available for further processing of the clean wafer.

The transfer module may use one or more robotic arms, each of which can move one or more wafers around corners of the transfer module. The transfer module may eliminate the requirement that a line connecting a center of each process facet of a transfer module and a center of the transfer module is perpendicular to the facet. The irregular polygon transfer module may allow its facets to support process modules attached to the facets more efficiently for maintenance. The transfer module may use different length facets. A minimum length of an individual facet may be determined by a width of a slot valve, while a maximum length of an individual facet may be determined by the required access. The transfer module may allow for access under the module through the use of a seventh double port face and two facets of longer length attached at the end of the seventh double port face. The transfer module may include an internal storage space for storing cover wafers and/or clean, but not processed wafers in the vacuum environment of the transfer module. Such internal storage space may eliminate, for example, issues of native growth oxide on clean wafers, while not expanding the footprint of the multi-module apparatus through the use of external facet mounted buffer stations.

One goal of the transfer module may be to provide a maintenance space on the sides of individual process modules and giving an access to the area under the transfer module for required maintenance while keeping the footprint of the multi-module apparatus to a minimum. The internal storage space for storing cover wafers and/or clean, but not processed wafers in the vacuum environment of the transfer module may keep the footprint of the multi-module apparatus from expanding. An external wafer storage station would have occupied a facet thereby increasing a footprint of the multi-module apparatus and/or decreasing a number of processing modules, which could be attached to the transfer module. The internal wafer storage space may increase the overall throughput of the multi-module apparatus dependent upon the process durations.

In some embodiments, the transfer module may be such that an angle between two adjacent facets is 12.5°. Such design may allow placing a processing module on each of the adjacent faces while allowing a greatly increased access space on a side of each of the process modules. The process modules may be designed for an easy access from either side of an individual processing module to components contained inside of it.

The transfer module may utilize the space below the wafer transfer plane for wafer storage, thereby merely utilizing a space within the transport module, which would have been otherwise unused.

Due to its design, the irregular polygon transfer module may use slightly slower robot speeds than other transfer modules, such as an equal sided polygon transfer module. This speed reduction may not outweigh the advantages of efficient spacing of processing modules in a multi-module apparatus allowed by the present transfer module. To compensate for a slower speed of a robot arm, the present irregular polygon transfer module may be used with process modules, such as the ones disclosed in U.S. provisional application No. 62/109,367 filed Jan. 29, 2015, which involve relatively slow processes and for which a faster speed of a robot arm may not be necessary.

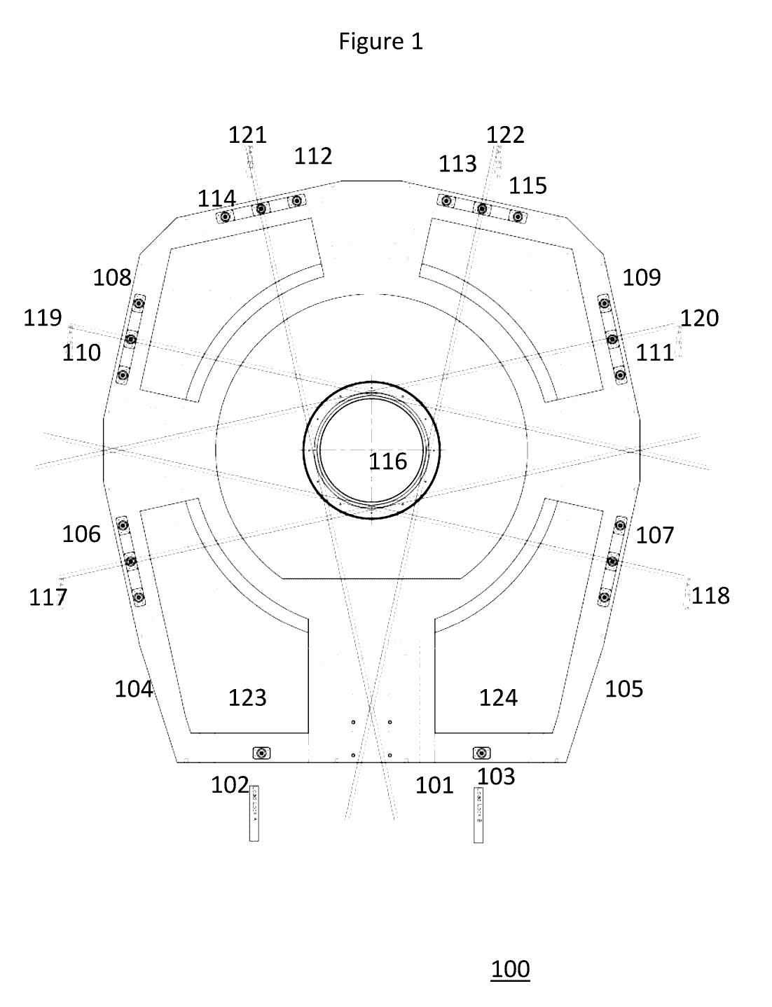

FIG. 1 shows a top view of a transfer module 100, which has a loading facet 101. The loading facet may have one or more loading ports for accessing a loading module. FIG. 1 shows that loading facet 101 has loading ports 102 and 103. A separate loading module may be attached to each of the loading ports 102 and 103. A loading module may be configured to transfer an object, such as a semiconductor substrate, from an atmospheric pressure outside environment to a lower pressure/vacuum environment of the transfer module and/or to transfer an object, such as a semiconductor substrate, which was treated in one or more modules of the apparatus, from the lower pressure/vacuum environment of the transfer module back to the atmospheric pressure outside environment. Preferably, the transfer module includes only one loading facet.

In FIG. 1, facets 104 and 105 are adjacent to loading facet 101. Each of facets 104 and 105 has a port for accessing its respective processing module. In FIG. 1, facet 104 has port 106, while facet 105 has port 107.

Facets 108 and 109 are adjacent to facets 104 and 105, respectively. Each of facets 108 and 109 has a port for accessing its respective processing module. In FIG. 1, facet 108 has port 110, while facet 109 has port 111.

Transfer module 100 may also have facets 112 and 113 adjacent to facets 108 and 109, respectively. Each of facets 112 and 113 has a port for accessing its respective processing module. In FIG. 1, facet 112 has port 114, while facet 113 has port 115.

A processing module attached to a port, such as ports 106, 107, 110, 111, 114 and 115 may be a module configured to perform a particular process, such as cleaning an object, such as a semiconductor substrate, or depositing additional materials on an object, such as a semiconductor substrate. Such depositing may be epitaxial deposition of a semiconductor material on a semiconductor substrate.

In some embodiments, a processing module is attached to each of ports 106, 107, 110, 111, 114 and 115. In such a case, a multi-module apparatus may have six processing modules total, i.e. one processing module per each port. Yet in some embodiments, there may be at least one port out of ports 106, 107, 110, 111, 114 and 115, to which no processing module is attached.

Individual processing modules attached to ports 106, 107, 110, 111, 114 and 115 may be same or different.

In some embodiments, at least one of processing modules attached to one of ports 106, 107, 110, 111, 114 and 115 may be a cleaning module, i.e. a module configured to clean an object, such a semiconductor substrate. In some embodiments, multiple, i.e. more than one, processing modules attached to ports 106, 107, 110, 111, 114 and 115 may be cleaning modules. In such a case, individual cleaning modules may be same or different. In some embodiments, at least one of processing modules attached to one of ports 106, 107, 110, 111, 114 and 115 may be a cleaning module disclosed in U.S. provisional application No. 62/109,367 filed Jan. 29, 2015.

In some embodiments, at least one of processing modules attached to one of ports 106, 107, 110, 111, 114 and 115 may be a deposition module, i.e. a module configured to deposit a material on an object, such as a semiconductor substrate. Such deposition module may be an epitaxial deposition module, i.e. a module configured to deposit an epitaxial layer on a substrate, such as a semiconductor substrate. In some embodiments, multiple, i.e. more than one, processing modules attached to ports 106, 107, 110, 111, 114 and 115 may be deposition modules. In such a case, individual deposition modules may be same or different.

The transfer module may have a shape of an irregular polygon. For example, in FIG. 1, transfer module 100 has a shape of an irregular heptagon formed by facets 101, 104, 105, 108, 109, 112 and 113.

In some embodiments, one or more intersections between facets of the transfer module may be chamfered. For example, in FIG. 1, the following intersections between facets of transfer module 100 are chamfered: a) an intersection between facets 104 and 108; b) an intersection between facets 108 and 112; c) an intersection between facets 112 and 113; d) an intersection between facets 113 and 109; e) an intersection between facets 109 and 105. Preferably, a mini-facet formed by chamfering of an intersection between facets of the transfer module cannot hold a processing module. For example, none of mini-facets formed by chamfering a) the intersection between facets 104 and 108; b) the intersection between facets 108 and 112; c) the intersection between facets 112 and 113; d) the intersection between facets 113 and 109; e) the intersection between facets 109 and 105 can hold a process module.

The transfer module has at least one robot arm, which may be configured to transfer an object, such as a semiconductor substrate, processed in the multi-module apparatus from an inner volume of the transfer module through a port on a facet to a module attached to the port. FIG. 1 does not show a robot arm, however, point 116 illustrates a rotational axis of the robot arm. As can be seen, a line or vertical plane 117 passing through a center of port 106 perpendicular to facet 104 does not pass through the rotational axis of the robot arm 116. The same thing applies to a line or vertical plane 118 passing through a center of port 107 perpendicular to facet 105; a line or vertical plane 119 passing through a center of port 110 perpendicular to facet 108; a line or vertical plane 120 passing through a center of port 111 perpendicular to facet 109; a line or vertical plane 121 passing through a center of port 114 perpendicular to facet 112; a line or vertical plane 122 passing through a center of port 115 perpendicular to facet 113.

A width, i.e. a dimension parallel to the plane of the module, of an individual port, such as ports 106, 107, 110, 111, 114 and 115 may depend on dimensions of an object, such as a semiconductor substrate to be transferred through the port. In general, a width of an individual port is no less than a width of an object transferred through the port. A width of an object may be one of the object's dimensions parallel to the plane of the module. In some embodiments, a width of an object may be the smallest of the object's dimensions parallel to the plane of the module. For round shape objects, such as round shape semiconductor substrates, a width may be a diameter. In some embodiments, a width of an individual port may be no more than 2.0 times a width of an object to be transferred through the port or no more than 1.8 or no more than 1.6 or no more than 1.5 or no more than 1.35 or no more than 1.4 or no more than 1.35 or no more than 1.3 or no more 1.25 or no more than 1.2 or no more than 1.15 or no more than 1.1 or no more than 1.05 times the object's width.

The transfer module may comprise one or more storage areas located in the low pressure/vacuum inner volume of the transfer module. FIG. 1 shows that transfer module 100 has within its low pressure/vacuum inner volume i) storage area 123 adjacent to loading facet 101 and facet 104 and ii) storage area 124 adjacent to loading facet 101 and facet 105. Storage areas 123 and 124 may be located within the transfer module's low pressure/vacuum inner volume below the plane of movement for the robot arm. Preferably, a storage area, such as one of storage areas 123 and 124, is positioned in-line with a movement of a robot arm to/from a loading module, such a loading module on loading port 102 or 103. Such arrangement may allow bringing an object, such as a semiconductor substrate, to the storage area when it is loaded into an inner volume of the transfer module from the loading module before the object is transferred to one of processing modules. Such arrangement may also allow bringing a processed object, such as semiconductor substrate, to the storage are on its way from the inner volume of the transfer module to the loading module. The movement of objects to and from the storage areas may be achieved by compound extension and rotational movements of the robot assembly, such as compound extension and rotational movements of the robot arms of the robot assembly.

Each of these storage spaces may be used for storing objects, such as semiconductor substrates, which are not being used at the moment by any of the processing modules attached to the transfer module. Such objects may be, for example, substrates, such as semiconductor substrates, which were processed in one of the processing modules attached to the transfer module before being transferred to another processing module. For example, a substrate, which was cleaned in a cleaning module attached to the transfer module may be stored in one or both of storage areas 123 and 124 before being transferred for a deposition in a processing module attached to the transfer module. Also, a substrate, which had undergone a deposition in a first deposition module attached to the transfer module, may be stored in one or both of storage areas 123 and 124 before being transferred to a second deposition module attached to the transfer module. Storage areas 123 and 124 may be also used for storing one or more test substrates, i.e. a substrate used in a test run in a processing module attached to the transfer module. Because the transfer module provides one or more internal storage areas, such as areas 123 and 124, a multi-module apparatus based on the transfer module can be without any external storage modules. This may allow for reduction of a footprint of the apparatus. Not using external storage modules may also allow one to use more processing modules, which may increase the efficiency of the apparatus.

In some embodiments, a storage, such as one of storage areas 123 and 124, may have a cover, which may be used to protect objects, such as semiconductor substrates, stored in the storage area from undesirable exposure.

Angles between i) facets 104 and 108 (defined as an angle between lines or vertical planes 117 and 119); ii) facets 105 and 109 (defined as an angle between lines or vertical planes 118 and 120) iii) facets 112 and 113 (defined as an angle between lines or vertical planes 121 and 122) may vary. In certain embodiments, each of these angles may be between 10° and 15° or between 12° and 13°. It may be preferred that each of these angles is 12.5°.

In some embodiments, an angle between a line or vertical plane 117 and a plane of loading facet 101, an angle between a line or vertical plane 118 and a plane of loading facet 101, an angle between a line or vertical plane 119 and a plane of loading facet 101, an angle between a line or vertical plane 120 and a plane of loading facet 101, an angle between a line or vertical plane 121 and a vertical plane perpendicular to loading facet 101, and an angle between a line or vertical plane 122 and a vertical plane perpendicular to loading facet 101 may be each between 10° and 15° or between 12° and 13°. It may be preferred that each of these angles is 12.5°.

In many embodiments, it may be preferred that a length of facets 104 and 105 is greater than a length of facets 108 and 109. This may allow accommodating storage areas, such as area 123 and 124 in the vacuum inner volume of the transfer module. The length of facets 104 and 105 may be at least 1.1 times greater or at least 1.2 times greater or at least 1.3 times greater or at least 1.4 times greater than the length of facets 108 and 109.

The transfer module may include a robot assembly. The robot assembly may include one or more robot arms, which may be configured to move an object, such as a semiconductor substrate, to and from a module attached to a port on one of the facets of the transfer module through the port through compound extension and rotational movements. A compound extension and rotational movement may refer to a movement of a robot arm that includes extension and rotational movements at the same time. In other words, a compound extension and rotational movement is a movement that includes simultaneous, or substantially simultaneous, extension and rotation of a robot arm.

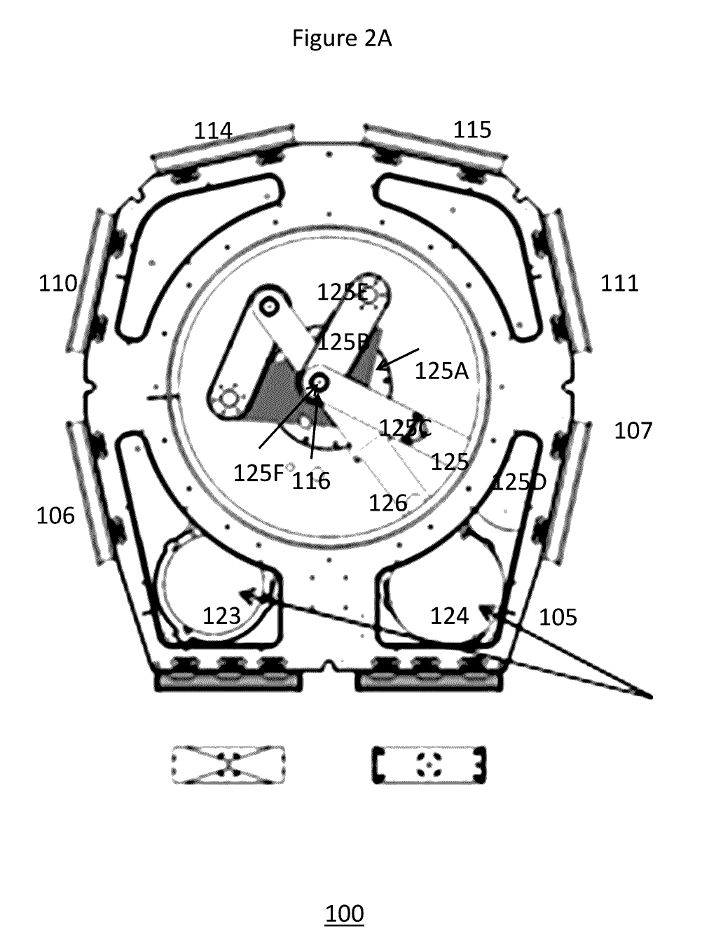

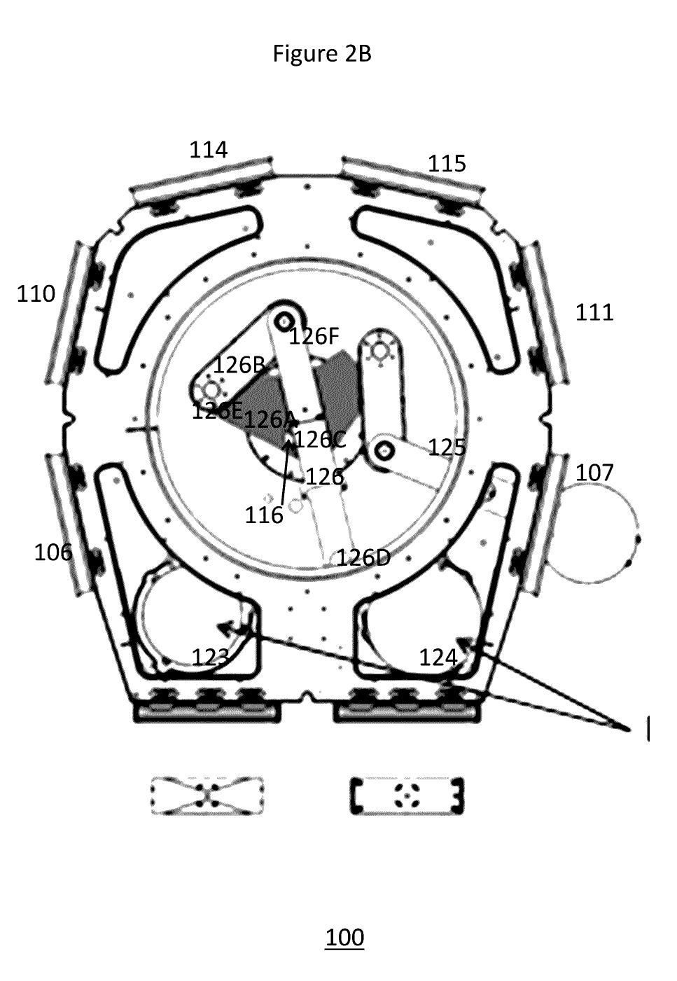

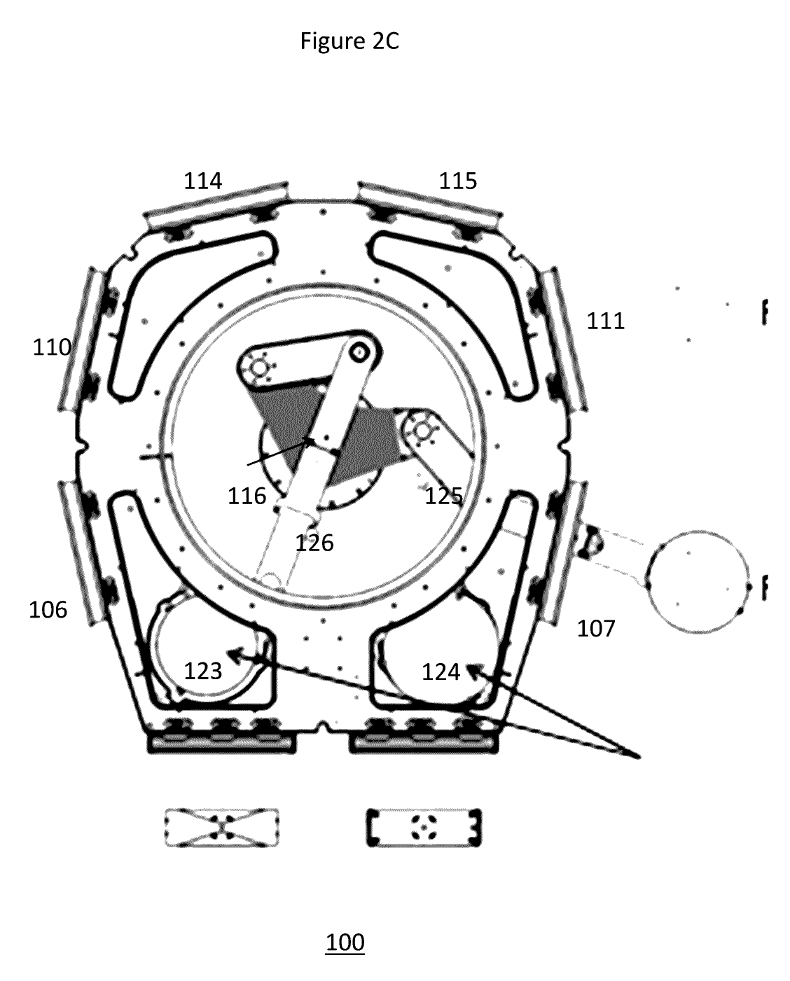

For example, FIGS. 2A-2C show a robot arm 125, which can move an object, such as a semiconductor substrate, to and from the inner volume of the transfer volume through a port on its facet through compound extension and rotational movements. In particular, FIG. 2A shows robot arm 125 is a fully contracted state, i.e. when an object, such as a semiconductor substrate, which is carried by the robot arm's end, is fully inside the inner volume of the transfer module; FIG. 2C shows robot arm 125 in a fully extended state, i.e. when an object, such as a semiconductor substrate, which is carried by the robot arm's end is fully outside the transfer module's inner volume; FIG. 2B shows robot arm 125 is a semi-extended state, i.e. when an object, such as a semiconductor substrate, which is carried by the robot arm's end, is passing through a port on a facet of the transfer module.

Robot arm 125 may include sections 125A, 125B and 125C. One end of section 125 A is attached at point 116, which illustrates the theta rotational axis of robot arm 125, the other end of section 125A includes joint 125E. Section 125B includes on one end joint 125E, through which section 125B is connected to section 125A, and on the other end, joint 125F, through which section 125B is connected to section 125C. Section 125C includes on one end joint 125F, through which section 125C is connected section 125B, and on the other end, section 125C includes handle 125D, which is configured to handle/carry an object, such as a semiconductor substrate, which is processed by a multi-module apparatus comprising the transfer module. Robot arm 125 has the following degrees of freedom: section 125A can rotate around axis 116; section 125B can rotate with respect to section 125A through single axis joint 125E; section 125C can rotate with respect to section 125B through single axis joint 125F. Through these degrees of freedom, robot arm 125 may move through compound extension and rotational movements. As the result of the extension, handle 125D, which may carry an object, such as a semiconductor substrate, may move to and from the inner volume of transfer module 100 through a port of its facet, such as port 107 on facet 105. As the result of the rotational movement around its rotational axis 116, robot arm 125 may move between ports on various facets, such as ports 106, 107, 109, 110, 114 and 115 as well as between storage areas, such as areas 123 and 124.

In some embodiments, the transfer module may include more than one robot arm. In some embodiments, the transfer module may include more than one robot arm, each of which may be configured to move an object, such as a semiconductor substrate, to and from a module attached to a port on one of the facets of the transfer module through the port through compound extension and rotational movements.

For example, FIGS. 2A-2C also illustrate robot arm 126, which has the same theta rotational axis as robot arm 125 and which similarly to robot arm 125, may move through compound extension and rotation movements. In this manner, the robot assembly, which includes robot arm 125 and robot arm 126, may have a single theta axis. Similarly to arm 125, arm 126 may include three sections, 126A, 126B and 126C. One end of section 126A is attached at point 116, which illustrates the theta rotational axis of robot arm 126, the other end of section 126A includes joint 126E. Section 126B includes on one end joint 126E, through which section 126B is connected to section 126A, and on the other end, joint 126F, through which section 126B is connected to section 126C. Section 126C includes on one end joint 126F, through which section 126C is connected section 126B, and on the other end, section 126C includes handle 126D, which is configured to handle/carry an object, such as a semiconductor substrate, which is processed by a multi-module apparatus comprising the transfer module. Robot arm 126 has the following degrees of freedom: section 126A can rotate around axis 116; section 126B can rotate with respect to section 126A through single axis joint 126E; section 125C can rotate with respect to section 126B through single axis joint 126F. Through these degrees of freedom, robot arm 126 may move through compound extension and rotational movement. As the result of the extension, handle 126D, which may carry an object, such as a semiconductor substrate, may move to and from the inner volume of transfer module 100 through a port of its facet, such as port 107 on facet 105. As the result of the rotational movement around its rotational axis 116, robot arm 126 may move between ports on various facets, such as ports 106, 107, 109, 110, 114 and 115 as well as between storage areas, such as areas 123 and 124. FIGS. 2A-2C show clockwise rotational movements of robot arm 126 from storage area 124 to storage are 123.

Each of robot arms 125 and 126 may have a capability of moving objects such as semiconductor substrates to and from a storage area, such as storage area 123 or 124.

Each of robot arms 125 and 126 may configured to move an object, such as a semiconductor substrate, to one or more modules attached to facets of the transfer module through compound extension and rotational movements. It may be preferred that each of robot arms 125 and 126 is configured to move an object, such as a semiconductor substrate, to each of modules attached to facets of the transfer module through compound extension and rotational movements. For example, each of robot arms 125 and 126 may be configured to move an object, such as a semiconductor substrate, through compound extension and rotational movements to and from each of the following modules: a loading module attached to port 102 and/or a loading module attached to port 103; a module attached to port 106; a module attached to port 107; a module attached to port 109; a module attached to port 110; a module attached to port 114 and a module attached to port 115.

The present transfer module may operate as a transfer module in a multimodule epitaxial deposition apparatus such as the one disclosed in U.S. provisional application No. 62/109,367 filed Jan. 29, 2015.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention.

All of the publications, patent applications and patents cited in this specification are incorporated herein by reference in their entirety.

What is claimed is:

1. A transfer module for a multi-module apparatus, comprising:
a) a plurality of facets, wherein a facet of said plurality comprises a port configured to hold a module; and
b) a robot assembly comprising one or more robot arms each configured to move an object a) to and from the module through said port and b) between facets of said plurality via compound extension and rotational movements.

2. The transfer module of claim 1, wherein the plurality of facets form an irregular polygon.

3. The transfer module of claim 2, wherein the plurality of facets form an irregular heptagon.

4. The transfer module of claim 3, wherein the plurality of facets comprise:
a) a loading facet comprising at least one loading port configured to a hold a loading module;
b) first and sixth facets, each of which is adjacent to the loading facet, each of the first and sixth facets has a port configured to hold a module;
c) second and fifth facets, which are adjacent to the first and the sixth facets respectively, each of the second and fifth facets has a port configured to hold a module;
d) third and fourth facets, which are adjacent to the second and the fifth facets respectively, each of the third and fourth facets has a port configured to hold a module, wherein i) for each facet of the first, the second, the fifth or the sixth facets, an angle between a vertical plane perpendicular to the facet and a plane of the loading facet is 12.5°; and ii) for each of the third and the fourth facets, a vertical plane perpendicular to the facet and a vertical plane perpendicular to the loading facet is 12.5°.

5. The transfer module of claim 4, wherein a length of each of the first and sixth facets is greater than a length of each of the second, third, fourth and fifth facets.

6. The transfer module of claim 4, wherein for the port of each of the first facet, the second facet, the third facet, the fourth facet, the fifth facet and the sixth facet, a line passing through a center of the port perpendicular to the port does not pass through a theta rotational axis of the robot assembly.

7. The transfer module of claim 4, wherein the robot assembly comprises a first robot arm and a second robot arm, wherein a theta rotational axis of the first robot arm is the same as a theta rotational axis of the second robot arm.

8. The transfer module of claim 4, wherein each robot arm of the one or more robot arms is configured to move the object to and from each of the loading module; a first module, which is held by the port of the first facet; a second module, which is held by the port of the second facet; a third module, which is held by the port of the third facet; a fourth module, which is held by the port of the fourth facet; a fifth module, which is held by the port of the fifth facet; and a sixth module, which is held by the port of the sixth facet, through the respective port via the compound extension and rotational movements.

9. The transfer module of claim 1, wherein the plurality of facets comprises a loading facet comprising at least one loading port configured to hold a loading module, which is configured to bring the object from (to) an atmospheric outside environment to (from) a vacuum inner volume of the transfer module

10. The transfer module of claim 9, wherein the plurality of facets comprises only one loading facet.

11. The transfer module of claim 10, wherein the loading facet comprises two loading ports each configured to hold a loading module.

12. The transfer module of claim 9, wherein the inner volume of the transfer module comprises one or more storage areas adjacent to the loading facet, the one or more storage areas are configured to store a plurality of objects and a robot arm of the one or more robot arms is configured to move one or more objects of said plurality of objects to and from the one or more storage areas.

13. The transfer module of claim 12, wherein each storage area of said one or more storage areas is in-line with a travel of a robot arm of the one or more robot arms to/from the loading port.

14. The transfer module of claim 12, wherein the one or more storage areas have a cover over the plurality of objects

15. The transfer module of claim 8, wherein each robot arm is configured to move the object to and from the ports configured to hold the first module, the second module, the third module, the fourth module, the fifth module, and the sixth module through the respective port via compound extension and rotational movements.
